(19) United States
(12) Patent Application Publication
(10) Pub. No.: US 2009/0054242 A1
(43) Pub. Date: Feb. 26, 2009

(54) SUPERCONDUCTING WIRE, METHOD OF MANUFACTURING THE SAME, ANTENNA COIL FOR NMR PROBE AND NMR SYSTEM USING THE SAME

(75) Inventors: Masaya Takahashi, Hitachinaka (JP); Michiya Okada, Mito (JP); Hiroyuki Yamamoto, Kokubunji (JP); Yoshihide Wadayama, Hitachiota (JP); Genzo Iwaki, Mito (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi, Ltd.

(21) Appl. No.: 12/193,076

(22) Filed: Aug. 18, 2008

(30) Foreign Application Priority Data
Aug. 21, 2007 (JP) 2007-214939

(51) Int. Cl. G01R 33/035; H01B 12/02; G01R 33/341; H01L 39/24; H01L 39/12

(52) U.S. Cl. 505/162; 505/230; 505/433; 324/318; 174/125.1

(57) ABSTRACT

A superconducting wire, a method of manufacturing the superconducting wire, an antenna coil and a NMR system are disclosed. At least a superconducting material, a paramagnetic material and a diamagnetic material are closely attached and integrated with each other to form a longitudinally continuous wire. The paramagnetic material and the diamagnetic material are arranged in such a manner that the magnetic properties of the paramagnetic material and the diamagnetic material substantially offset each other in the longitudinal and diametrical directions. A superconducting layer is exposed to a part or the whole of the outer periphery of the wire. A low-resistance material layer is formed inside the superconducting layer.

### BACKGROUND OF THE INVENTION

This invention relates to a superconducting wire, a method of manufacturing the superconducting wire, an antenna coil for a probe of a nuclear magnetic resonance (NMR) system and a NMR system using the antenna coil.

The NMR probe is configured of an antenna coil for transmitting a radio-frequency signal and receiving a FID (Free Induction Decay) signal, a coil bobbin and an electrical circuit. The antenna coil forms a tuning circuit in combination with a tuning capacitor and receives the FID signal generated from resonators in a sample by the radiation of a radio-frequency pulse.

The NMR probe for receiving the FID signal generated in response to the radio-frequency pulse, on the other hand, requires a high sensitivity. This is because a vast amount of time is required for measuring a small quantity of sample such as protein, in which the strength of the FID signal is especially weak and the sensitivity is reduced.

This sensitivity can be effectively improved by increasing the Q value of a tuning circuit. The Q value indicates the sharpness of a peak in a resonance circuit and can be obtained from the next Equation (1).

$$Q = \frac{1}{R} \sqrt{\frac{L}{C}} \qquad ( 1 )$$

where R is the resistance, C the capacitance and L the inductance.

On the other hand, the NMR probe also requires a high resolution. The resolution can be improved effectively by reducing the magnetic susceptibility specific to a substance forming the antenna coil and by reducing the distortion of the static magnetic field to the absolute minimum. An antenna coil having these characteristics is described, for example, in JP-A-2003-11268.

### SUMMARY OF THE INVENTION

JP-A-2003-11268 discloses an application of a laminate material of metal foils and films to the material of the antenna coil to reduce the magnetic susceptibility. In the conventional manufacturing method, the compounding ratio of the materials used is determined by the thicknesses of the foil, the film and the plate combined to achieve a low magnetism. In this way, a structure of a low magnetic susceptibility can be acquired. However, since the thickness of the resulting material is reduced and the area resistance (R) of the cross-section of the material is reduced, the Q value cannot be improved. In order to improve the Q value, an increased size of the antenna coil as a whole or a multi-stage antenna structure is required, resulting in a size enlargement of the end portion of the probe.

In view of this situation, the object of this invention is to provide a superconducting wire having both a low magnetism and a high Q value at the same time, an antenna coil formed of the superconducting wire and a NMR system using the antenna coil.

According to one aspect of this invention, there is provided a longitudinally continuous superconducting wire configured of at least a superconducting material, a paramagnetic material and a diamagnetic material mutually attached and integrated with each other, wherein the paramagnetic material and the diamagnetic material are arranged in such a manner that the magnetism of the paramagnetic material and that of the diamagnetic material substantially offset each other in longitudinal and diametrical directions, wherein a superconducting layer is exposed in part or in whole of the outer periphery of the wire, and wherein a low-resistance material layer is formed inside of the superconducting layer.

According to another aspect of the invention, there is provided a method of manufacturing the superconducting wire by wire drawing, wherein the superconducting material, the paramagnetic material, the diamagnetic material and the low-resistance material are mutually attached and clad integrally with each other, and wherein the volume ratio between the paramagnetic material and the diamagnetic material is adjusted in such a manner that the magnetism of the paramagnetic material and that of the diamagnetic material offset each other.

According to still another aspect of the invention, there is provided an antenna coil for a NMR system wherein the wire material of the antenna coil of the NMR probe for detecting the NMR signal is the superconducting wire, and wherein the antenna coil is formed as a solenoid.

According to yet another aspect of the invention, there is provided a NMR system for detecting the NMR signal using the NMR probe.

According to a further aspect of the invention, there is provided an antenna coil of a NMR probe for detecting the NMR signal, configured of a combination of two or more types of materials having different magnetic properties and clad integrally into a round form, wherein the magnetic properties of the combined materials offset each other, wherein a superconducting layer is exposed in part or in whole of the outer peripheral of the wire and a low-resistance material layer is arranged on the immediate inside of the superconducting layer, and wherein the antenna coil is formed as a solenoid. In particular, there is provided an antenna coil of the NMR probe and a material thereof for a NMR system used for transmitting a radio-frequency signal at a predetermined resonance frequency to a sample arranged in a uniform magnetic field and receiving a FID signal. The invention is applicable further to an analysis apparatus utilizing a highly uniform magnetic field like NMR.

This invention provides a superconducting wire having both a high Q value and a low magnetism, a method of manufacturing the superconducting wire, an antenna coil using the wire and a NMR system. Also, a NMR probe having both a high sensitivity and a high resolution can be formed.

Other objects, features and advantages of the invention will become apparent from the following description of the embodiments of the invention taken in conjunction with the accompanying drawings.

### BRIEF DESCRIPTION OF THE DRAWINGS

FIG. 1 is a perspective view showing a general configuration of the NMR antenna coil according to this invention.

FIG. 2 is a cross-sectional view showing a configuration of the low-magnetism superconducting wire fabricated according to a first embodiment of the invention.

FIG. 3 is a cross-sectional view showing another configuration of the low-magnetism superconducting wire fabricated according to the first embodiment of the invention.

FIG. 4 is a cross-sectional view showing still another configuration of the low-magnetism superconducting wire fabricated according to the first embodiment of the invention.

FIG. 5 is a cross-sectional view showing yet another configuration of the low-magnetism superconducting wire fabricated according to the first embodiment of the invention.

FIG. 6 is a cross-sectional view showing a further configuration of the low-magnetism superconducting wire fabricated according to the first embodiment of the invention.

FIG. 7 is a cross-sectional view showing a configuration of the low-magnetism superconducting wire fabricated according to a second embodiment of the invention.

FIG. 8 is a cross-sectional view showing another configuration of the low-magnetism superconducting wire fabricated according to the second embodiment of the invention.

FIG. 9 is a perspective view showing a general configuration of the NMR measurement system according to the invention.

FIG. 10 is a perspective view showing the configuration of the end portion of the probe according to an embodiment of the invention.

### DETAILED DESCRIPTION OF THE EMBODIMENTS

Examples of specific embodiments of the invention are explained below.

(1) A superconducting wire wherein the low-resistance material is selected from Al, Au, Cu and alloys thereof.
(2) The paramagnetic material is selected from Al, Pt, Cr, Ta, W, K, Ca, Sc, Ti, V, Mn, Rb, Sr, Y, Zr, Nb, Mo, Tc, Ru, Rh, Pd and alloys thereof.
(3) The diamagnetic material is selected from Au, Ag, Cu and alloys thereof.
(4) The superconductor is selected from a Nb-based superconductor, MgB₂ and an oxide superconductor.
(5) The Nb-based superconductor is selected from NbTi, NbZr, Nb₃Sn and Nb₃Al.
(6) The method of manufacturing the superconducting wire wherein the diamagnetic material existing on the outer periphery of the superconductor after wire drawing is partially or wholly removed thereby to expose the superconductor.
(7) The method of manufacturing the superconducting wire wherein the diamagnetic material is dissolved by an acid.
(8) The method of manufacturing the superconducting wire wherein the low-resistance material is selected from Al, Au, Cu and alloys thereof.
(9) The method of manufacturing the superconducting wire wherein the paramagnetic material is selected from Al, Pt, Cr, Ta, W, K, Ca, Sc, Ti, V, Mn, Rb, Sr, Y, Zr, Nb, Mo, Tc, Ru, Rh, Pd and alloys thereof.
(10) The method of manufacturing the superconducting wire wherein the diamagnetic material is selected from Au, Ag, Cu and alloys thereof.
(11) The method of manufacturing the superconducting wire wherein the superconductor is selected from a Nb-based superconductor, MgB₂ and an oxide superconductor.
(12) The method of manufacturing the superconducting wire wherein the Nb-based superconductor is at least selected one of NbTi, NbZr, Nb₃Sn and Nb₃Al.
(13) The antenna coil for the NMR system wherein the wire of the antenna coil of the NMR probe for detecting the NMR signal is the superconductor described above, and the antenna coil is formed as a solenoid.
(14) The NMR probe required to use the antenna coil for detecting the NMR signal, wherein the antenna coil is formed of a combination of at least two materials of different magnetic properties clad integrally into a circular shape, wherein the magnetic properties of the combined materials offset each other, and wherein a superconducting layer is partially or wholly exposed to the outer peripheral portion of the wire, wherein a low-resistance material layer exists on the immediate inside of the superconducting layer, and wherein the antenna coil is formed as a solenoid.
(15) The low-magnetism superconducting wire required to be used as a material of the antenna coil of the NMR probe, wherein the material is a combination of at least two types of materials having different magnetic properties clad integrally into a round wire, wherein the magnetic properties of the combined materials offset each other, wherein a superconductor is partially or wholly exposed to the outer peripheral portion of the wire, wherein a low-resistance material layer exists on the immediately inside of the superconductor, and wherein the exposed superconductor may be arranged on the outer peripheral layer or in the longitudinal direction of the wire in plural bundles.
(16) The antenna coil of the NMR probe, wherein the material of the antenna is a single continuous wire free of a connecting point.
(17) The low-magnetism wire and the low-magnetism superconducting wire manufactured by the method of manufacturing the low-magnetism superconducting wire by wire drawing mainly including extrusion and drawing.

In order to provide an antenna coil formed of a material low in magnetic susceptibility and high in Q value and such a material, a paramagnetic material and a diamagnetic material are required to be combined to reduce the magnetic susceptibilities thereof by canceling with each other, while at the same time satisfying the following items of requirement for improving the Q value at the same time.

1.1 A material low in resistance value is formed into a round wire to increase the cross-sectional area thereof for a reduced resistance.
1.2 The temperature of the installation place of the antenna coil is reduced for a lower resistance.
1.3 The resistance value is reduced to the absolute minimum by employing a superconducting material.

First, an antenna coil is formed by the conventional method as a comparative material, and the magnetic susceptibility and the Q value (resonated at 300 MHz) are measured. As a result, the magnetic susceptibility is 1.5×10⁻⁷ (volume magnetic susceptibility) and the Q value 300. In the embodiments described below, the materials are compared with this data and evaluated.

Embodiments of the invention are explained below with reference to the drawings.

### First Embodiment

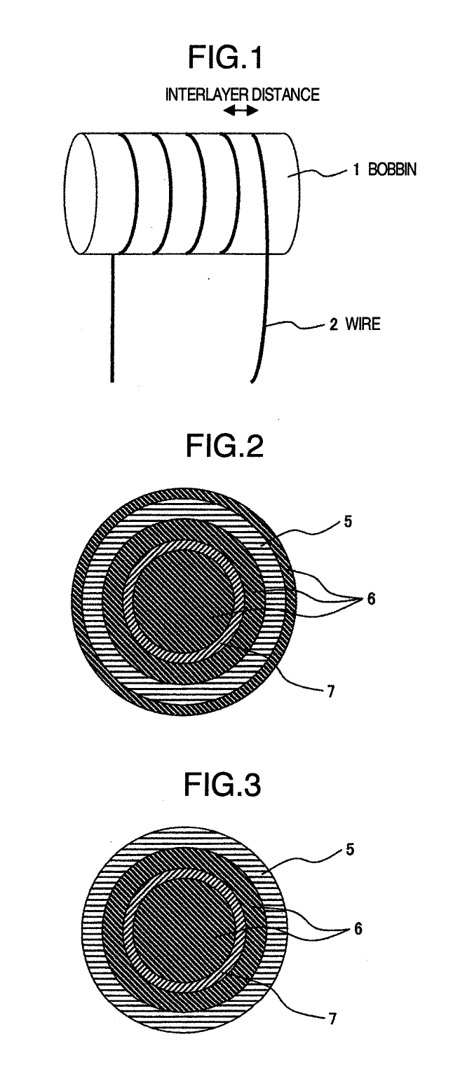

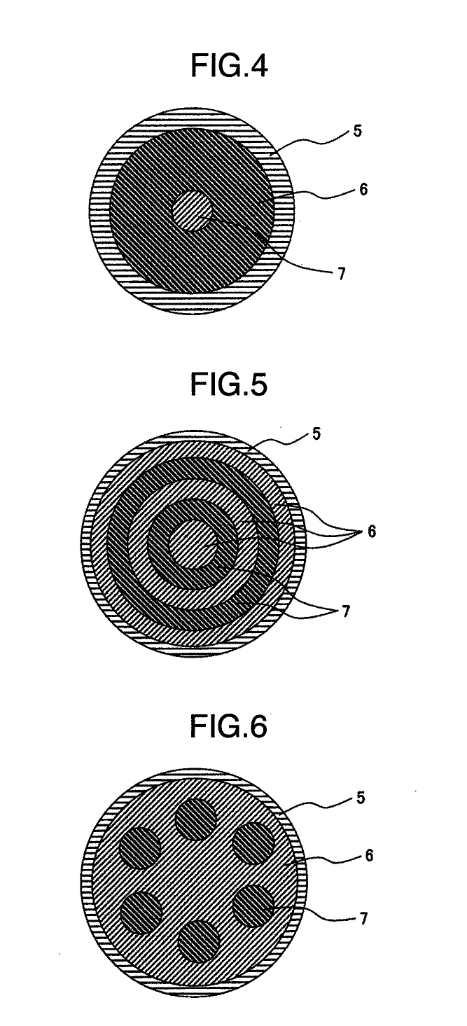

FIG. 1 shows the shape of an antenna coil, and FIGS. 2 to 6 show various cross-sectional structures of the NbTi wire as a low-magnetism superconducting wire manufactured according to this embodiment. According to this embodiment, Ta is used as a paramagnetic material 7 forming the base material, and Cu as a diamagnetic material 6. By forming this antenna coil material into a round wire, a superconducting wire is formed. Thus, the resistance can be reduced extremely and the Q value remarkably improved.

Also, the structure with the wire wound on a bobbin 1 improves the strength of the antenna coil as a whole, thereby making it possible to form a strong NMR probe. Further, since the antenna coil is formed of a single wire without any connecting portion, the resistance which otherwise might be generated at the connecting portion is avoided.

The manufacturing process of the superconducting wire according to this embodiment of the invention is described below.

The following members required for manufacturing the wire are prepared:

(1) Cu tube for an outermost layer
(2) NbTi tube, Cu tube and Ta tube for an intermediate layer
(3) Cu rod as an innermost layer

These members are assembled sequentially, and clad by wire drawing, followed by drawing to φ1.0 mm thereby to manufacture a Cu/NbTi/Cu/Ta composite wire. In the process, the size and thickness of the Cu tube for the intermediate layer, the Cu rod and the Ta tube are determined in such a manner that the compounding ratio at which the magnetism infinitely approaches zero by measuring the magnetic susceptibility of the materials to be used, under the same conditions as the operating conditions of the antenna coil.

In the superconducting wire according to the invention, a low-resistance layer 6 is arranged on the immediate inside of the superconductor layer 5. The low-resistance layer 6 and the diamagnetic material 6 may be formed of the same substance. The low-resistance layer 6 arranged on the immediate inside of the superconductor layer 5, however, is formed of selected one of Al, Au, Ag, Cu and alloys thereof.

Next, the Cu existing in the outermost layer is wholly dissolved with nitric acid thereby to expose the NbTi layer 5. This Cu has been covered on the outer periphery for the purpose of wire drawing for the reason that the exposure of the superconductor makes the drawing process difficult in the case where the outermost layer is formed of Nb or NbTi. In all the cross-sectional views of FIGS. 3 to 7, the superconductor 5 is shown exposed to the outer periphery after the Cu covering shown in FIG. 2 has been removed.

FIG. 8 shows a structure with a plurality of bundles 5 of the superconducting wire (filament) embedded in one of the diamagnetic layers 6. In this case, the outer peripheral portion 9 of each of the superconducting wire bundles 5 is removed by a chemical means such as an acid solution or a mechanical means such as grinding to expose the superconducting wire bundles. Although the low-resistance layer and the diamagnetic layer are integrated with each other in FIG. 8, the Cu layer 6 apparently exists inside the superconducting wire.

Next, the magnetization of the NbTi/Cu/Ta composite wire thus manufactured is measured. As a result, the volume magnetic susceptibility is found to be −9.0×10⁻⁸ which is a minuscule value substantially corresponding to the compounding ratio.

Next, the NbTi/Cu/Ta composite wire 2 thus manufactured is wound in coil on a bobbin 1 formed of a low-magnetism material such as quartz glass, and the Q value was measured. As a result, Q is found to be 2000 (for 500 MHz) far exceeding the Q value of the conventional structure.

The foregoing result of measurement shows that an antenna coil wire and an antenna coil having both a very high Q value and a low magnetism can be formed by use of the superconducting wire reduced in magnetic susceptibility.

Similar effects can be obtained also by the methods described below.

(a) As a paramagnetic material, Al, Pt, Cr, Ta, W, K, Ca, Sc, Ti, V, Mn, Rb, Sr, Y, Zr, Nb, Mo, Tc, Ru, Rh, Pd or any alloy thereof is effective, while as a diamagnetic material, Au, Ag, Cu or an alloy thereof is advantageous. To produce effects as expected, however, Al, Ta or Nb is a suitable paramagnetic material and Cu or a Cu alloy such as CuNi or CuSn is desirable as a diamagnetic material, considering the tenacity or the material cost required for manufacturing the low-resistance material or the wire. An alloy, however, has variations of composition and the magnetic susceptibility thereof may vary depending on the material used. Therefore, a material having few impurities is desirable. Also, a low-resistance material equivalent to Au, Ag or Cu is required to form a layer on the immediate inside of the superconducting layer.
(b) As a cross-sectional structure of the wire, as shown in FIGS. 3 to 5, a structure having Ta at the central portion, a quintuple structure or a Ta multi-core structure with Ta dispersed in the same cross-section plane can produce similar effects. Also, the arrangement of Cu and Ta may be reversed or a structure with three or more types of materials combined as shown in FIG. 6 can produce similar effects.
(c) The drawbench process, the extrusion process or other wire drawing processes, hydrostatic press or the rolling process can produce similar effects as the wire drawing process.
(d) The diameter after the final machining process, though set to φ1.0 mm according to this embodiment, can be arbitrarily determined according to the specification of the inductance or size of the antenna coil. Nevertheless, a size in the range from φ0.1 mm to φ3.0 mm is desirable for actual operation.
(e) According to this embodiment, the wire is manufactured with the volume magnetic susceptibility of −9.0×10⁻⁸. In the case where the compounding ratio is changed due to the effect of wire drawing, however, a low magnetism can be achieved by fine adjustment by forming a predetermined film on the outermost layer. In the case where the wire completely machined has a diamagnetic property, for example, a film of a paramagnetic material such as Pt or V is formed. In the process, the thickness and the material not affecting the current conduction characteristic after forming the film are desirable. Also, the film is desirably formed either by a dry or wet method in which the film thickness is easy to adjust.
(f) Though the above is described as a round wire, a similar effect can be obtained if the wire is formed in such a shape as hexagon or square.

Nevertheless, the use of a superconducting layer is not always accompanied by a high Q value as described in the embodiments below.

### Second Embodiment

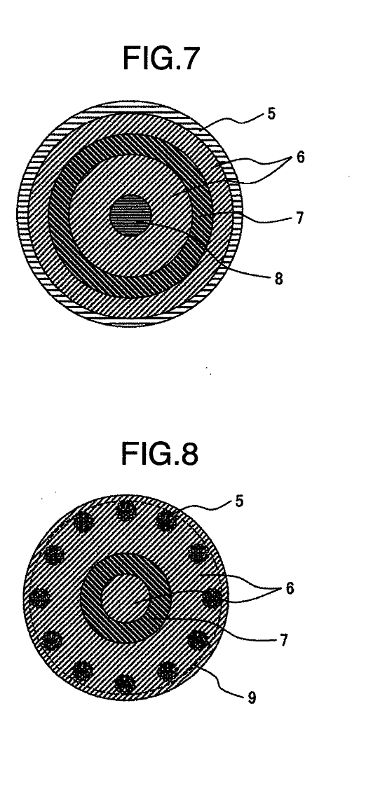

According to this embodiment, wires having a composite multi-core structure of the NbTi superconducting layer as shown in FIG. 7 are manufactured, and using these wires the Q value is measured. According to this embodiment, to study the effects of other than the superconducting layer, Cu or CuSn is used for the diamagnetic material shown in FIG. 7, and the effects thereof are studied.

First, a NbTi rod is assembled into a Cu or CuSn alloy tube, and a single-core NbTi wire is fabricated by wire drawing. This wire is again assembled into each of 19 holes formed in a Cu or CuSn tube, a multi-core NbTi wire is fabricated by wire drawing. This multi-core NbTi wire is again assembled into each of holes formed in the outer layer and the central portion of a Cu or CuSn tube thereby to complete a NbTi billet. A Ta tube for the intermediate layer and a Cu rod for the innermost layer are assembled in that order into the central portion of the billet thus completed, after which the assembly is clad by wire drawing, followed by drawing to φ1.0 mm, while at the same time being subjected to the intermediate annealing. In this way, a NbTi composite wire is manufactured. In the process, the magnetic susceptibility of each material to be used is measured under the same condition as the environment in which the antenna coil is used, and the size and thickness of CuSn, Cu and Ta are determined to attain a compounding ratio at which the magnetism is infinitely approximate to zero.

The Cu or CuSn portion of the wire thus fabricated is dissolved with nitric acid thereby to expose the NbTi layer partially. By winding the resulting assembly in the form of solenoid coil on a similar bobbin, the Q values of the respective coils are measured. As a result, the Q value of the Cu-based coil is 20000 as in the first embodiment, while the Q value of the CuSn-based coil is 2000, which is very small as compared with the antenna coil using a Cu-based wire. Therefore, because the Q value is considered to have decreased, the resistance of the layer supporting the superconducting layer becomes high. This is also the case with Ag and Au as well as Cu. In other words, unless a material with a resistance as low as Cu is used, the antenna coil having a high Q value is difficult to manufacture.

The foregoing fact indicates that the material used for supporting the superconducting layer or for the layer on the immediate inside is required to have a resistance as low as Cu.

With this composite multi-core structure, similar effects can be produced also with the methods described below.

(i) As materials that can be combined, though similar to those of the first embodiment, desirably have a melting point of not lower than 400° C., since they may be subjected to an ageing heat treatment for NbTi.
(ii) Any cross-sectional structure of the wire may be employed as in the first embodiment, as long as the central portion is maintained at the proper compounding ratio of Ta and Cu, to produce similar effects.
(iii) The wire drawing which produces similar effects includes the drawbench process, the extrusion process, other wire drawing processes, the hydrostatic press process and the rolling process.
(iv) The diameter after the final machining process, though set to φ1.0 mm according to this embodiment, may be optionally determined in accordance with the specification such as the inductance or size of the antenna coil. For actual operation, however, the figure in the range of φ0.1 mm to φ3.0 mm is desirable.
(vi) In the manufacture of the wire according to this embodiment, the volume magnetic susceptibility is set to −6.0×10⁻⁸. In the case where the compounding ratio is changed as an effect of wire drawing, however, as in the first embodiment, the magnetism can be reduced by forming a predetermined film on the outermost layer for fine adjustment.
(vii) The shape of the wire, though the above is described as round, may alternatively be hexagonal or rectangular with similar effects.
(viii) The diameter of the superconducting filament, though set to 5 μm above, is desirably smaller to achieve a higher Q value.
(ix) According to this embodiment, 228 filaments of the superconducting layer are fabricated. Similar effects can be produced, however, by the number of filaments which can secure at least the required Ic. However, for adjusting the magnetic properties of the superconducting filaments, it is desirable that substantially the same number of filaments as equivalent to the required Ic are employed.
(x) Dissolving by nitric acid is generally employed as a desirable means of exposing the superconducting layer. In order to dissolve a predetermined amount of CuSn, the solution is required to be adjusted in advance. Although other solutions or melted metals may be used, it is important to expose Nb₃Sn directly, and accordingly, a process after which the solution is left on the outer periphery is not desirable.

The aforementioned facts are substantiated with NbTi. Nevertheless, Nb₃Sn or other superconducting materials can produce similar effects, as described in the embodiment below.

### Third Embodiment

This embodiment concerns a case in which the superconducting filament is formed of NbTi, NbAl or MaB₂.

As in the embodiments described above, similar effects can be produced also by a combination of materials other than described above as long as a low magnetic susceptibility can be achieved. Also, the superconducting layer is desirably exposed to an external environment. The other points also exhibit the substantially similar trend to those of the embodiments described above. It is important, however, to select them in keeping with the operating environment of the antenna coil. NbTi high in flexibility is effective in a magnetic flux density of 10 T or less, while MgB₂ or an oxide not lower than 20 T. Also, Nb₃Sn or Nb₃Al is effective in a high magnetic flux density of not lower than 20 T. Further, an effective superconducting can be fabricated by a well-known method. On the other hand, in an application of the invention to a superconducting wire requiring heat treatment, it is important to use a material having a melting point not lower than the heat treatment temperature.

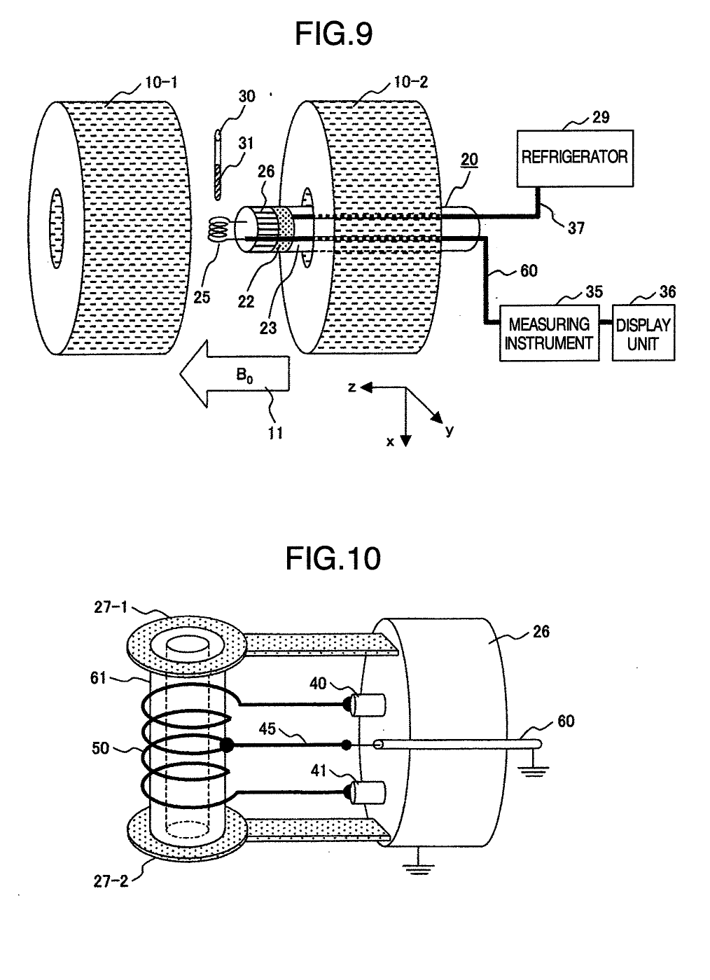

FIG. 9 is a schematic diagram showing a NMR system according to this invention. In FIG. 9, reference numerals 10-1, 10-2 designate a superconducting magnet, numeral 11 a uniform magnetic field, numeral 20 a low-temperature probe, numeral 22 a heat exchanger, numeral 23 a probe housing, numeral 25 a probe antenna, numeral 26 a stage at the forward end of the probe, numeral 29 a refrigerator, numeral 30 a sample tube, numeral 31 a sample, numeral 35 a measuring instrument, numeral 36 a display unit, and numeral 37 a cooling gas line. In the NMR system, the sample tube 30, with a minuscule amount of the sample placed in the sample tube 30, is arranged at a position coincident with the probe antenna 25 in the measurement space having a uniform magnetic field formed around a magnet. The magnetic field is required to be uniform in x, y and z directions.

FIG. 10 is a perspective view showing the structure of the forward end portion of the probe according to this invention, and shows the probe structure of FIG. 9 in an enlarged form. In FIG. 10, numeral 26 designates the stage at the end of the probe, numerals 27-1 and 27-2 support plates, numerals 40, 41 trimmer capacitors, numeral 45 a tap line, numeral 50 an antenna coil, numeral 60 a signal line and numeral 61 a bobbin.

It should be further understood by those skilled in the art that although the foregoing description has been made on embodiments of the invention, the invention is not limited thereto and various changes and modifications may be made without departing from the spirit of the invention and the scope of the appended claims.

1. A superconducting wire comprising:
at least a superconducting material exposed in part or in whole of the outer periphery of the wire;
a paramagnetic material and a diamagnetic material integrated by being arranged adjacent as a longitudinally continuous wire in such a manner that the magnetism of said paramagnetic material and the magnetism of said diamagnetic material substantially offset each other in the longitudinal and diametrical directions of said wire; and
a low-resistance material arranged inside the superconductor.

2. The superconducting wire according to claim 1,
wherein said low-resistance material is selected one of Al, Au, Cu and any alloy thereof.

3. The superconducting wire according to claim 1,
wherein said paramagnetic material is selected one of Al, Pt, Cr, Ta, W, K, Ca, Sc, Ti, V, Mn, Rb, Sr, Y, Zr, Nb, Mo, Tc, Ru, Rh, Pd and any alloy thereof.

4. The superconducting wire according to claim 1,
wherein said diamagnetic material is selected one of Au, Ag, Cu and any alloy thereof.

5. The superconducting wire according to claim 1,
wherein said superconducting material is selected one of a Nb-based superconductor, MgB₂ and an oxide superconductor.

6. The superconducting wire according to claim 5,
wherein said Nb-based superconductor is formed of at least selected one of NbTi, NbZr, Nb₃Sn and Nb₃Al.

7. A method of manufacturing a superconducting wire,
wherein a superconducting material, a paramagnetic material, a diamagnetic material and a low-resistance material are adjacent and clad integrally with each other and subjected to wire drawing process while at the same time adjusting the volume ratio between said paramagnetic material and said diamagnetic material in such a manner that the magnetic properties of said paramagnetic material and said diamagnetic material offset each other.

8. The method of manufacturing the superconducting wire according to claim 7,
wherein said superconductor is exposed by removing a part or the whole of said diamagnetic material existing on the outer periphery of said superconducting material after said wire drawing process.

9. The method of manufacturing said superconducting wire according to claim 8,
wherein said diamagnetic material is dissolved off by an acid.

10. The method of manufacturing the superconducting wire according to claim 7,
wherein said low-resistance material is selected one of Au, Ag, Cu and any alloy thereof.

11. The method of manufacturing the superconducting wire according to claim 7,
wherein said paramagnetic material is selected one of Al, Pt, Cr, Ta, W, K, Ca, Sc, Ti, V, Mn, Rb, Sr, Y, Zr, Nb, Mo, Tc, Ru, Rh, Pd and any alloy thereof.

12. The method of manufacturing the superconducting wire according to claim 7,
wherein said diamagnetic material is selected one of Au, Ag, Cu and any alloy thereof.

13. The method of manufacturing said superconducting wire according to claim 7,
wherein said superconducting material is selected one of a Nb-based superconductor, MgB₂ and an oxide superconductor.

14. The method of manufacturing the superconducting wire according to claim 13,
wherein said Nb-based superconductor is formed of at least selected one of NbTi, NbZr, Nb₃Sn and Nb₃Al.

15. An antenna coil of the probe of a nuclear magnetic resonance (NMR) system,
wherein the wire of said antenna coil of said NMR probe for detecting NMR signal is the superconducting wire described in claim 1, and said antenna coil is formed as a solenoid.

16. The antenna coil of the probe of a nuclear magnetic resonance system according to claim 15,
wherein said superconducting wire forming said antenna is a single continuous wire.

17. A nuclear magnetic resonance system for detecting the NMR signal using said antenna coil of said probe of the nuclear magnetic resonance system according to claim 16.
